(19) United States
(12) Patent Application Publication
(10) Pub. No.: US 2025/0132706 A1
(43) Pub. Date: Apr. 24, 2025

(54) MONITORING MODULE, X-RAY DIFFRACTION APPARATUS, AND MONITORING SYSTEM

(71) Applicant: Rigaku Corporation, Tokyo (JP)

(72) Inventors: Yuji HATAYAMA, Tokyo (JP); Yoshihiro IBA, Tokyo (JP); Tomoyasu UEDA, Tokyo (JP)

(73) Assignee: Rigaku Corporation, Tokyo (JP)

(21) Appl. No.: 18/923,778

(22) Filed: Oct. 23, 2024

(30) Foreign Application Priority Data
Oct. 24, 2023 (JP) 2023-182868

(51) Int. Cl. H02P 8/34; G01N 23/20016; G01N 23/20025

(52) U.S. Cl. CPC H02P 8/34; G01N 23/20016; G01N 23/20025; H02P 2209/09

(57) ABSTRACT

A monitoring module, an X-ray diffraction apparatus and a monitoring system capable of guaranteeing driving at a constant speed and maintaining traceability of each measurement are provided. A monitoring module for monitoring an operation of a stepping motor used in an X-ray diffraction apparatus, comprises a detection section for detecting a specific rotational position of a stepping motor and generating a detection signal, a measurement section for measuring a time interval of the detection signal, a determination section for determining whether or not a measurement value corresponding to the time interval of the detection signal coincides with a reference value corresponding to a rotation time between the specific rotational positions determined based on an operation instruction to the stepping motor and an information transmitting section for transmitting operation abnormality information to an outside when the measurement value does not coincide with the reference value.

### CROSS-REFERENCE TO RELATED APPLICATION

This application claims priority from Japanese Patent Application No. 2023-182868, filed on Oct. 24, 2023, the entire contents of Japanese Patent Application No. 2023-182868 are incorporated herein by reference.

### BACKGROUND

### Field

The present disclosure relates to a monitoring module, an X-ray diffraction apparatus and a monitoring system for monitoring an operation of a stepping motor.

### Description of the Related Art

The X-ray diffraction apparatus is provided with various driving mechanisms using a stepping motor for moving a goniometer or a sample. Basically, the operation failure is prevented by periodically performing the maintenance of the driving mechanism using a stepping motor having sufficient slack for the torque required at the time of driving, but the monitoring of the operation of the stepping motor is also important. A stepping motor with an encoder detects an abnormal operation of the stepping motor from a difference between a command pulse to the stepping motor and a current position of the encoder.

However, when a stepping motor with an encoder is used, (1) the cost of the motor is expensive, (2) the size of the motor is large, and mechanical interference is likely to occur. When the operation of the stepping motor is not monitored, step-out may occur due to deterioration of grease or the like of the drive mechanism, and abnormality cannot be detected at that time. In this case, the step-out is often estimated from the abnormality of the measurement profile. In this case, it is difficult to identify when the abnormality has occurred, and it is difficult to maintain the traceability of each measurement profile.

In response, a technique for performing step-out detection of a stepping motor using an origin sensor is known (see Patent Document 1). The apparatus described in Patent Document 1 counts a command pulse during motor rotation and determines that step-out has occurred when the value of the counter exceeds the pulse number for one rotation of the motor before the output of the origin position sensor is performed, thereby detecting step-out of the motor without an encoder.

### Patent Document

### Patent Document

Patent Document 1: JP H09-093993 A1

However, although the apparatus described in Patent Document 1 can detect step-out, it is not possible to detect an abnormality in a case where a pulse is not output due to a failure of the pulse motor controller or in a case where the origin sensor output despite less than one rotation due to a failure of the sensor or the like.

### SUMMARY

The present disclosure has been made in view of such circumstances, and an exemplary embodiment of the present disclosure is to provide a monitoring module, an X-ray diffraction apparatus and monitoring system capable of guaranteeing that a stepping motor is driven at a constant speed and maintaining traceability of each measurement.

(1) For example, the monitoring module of the present disclosure is a monitoring module for monitoring an operation of a stepping motor used in an X-ray diffraction apparatus, a detection section for detecting a specific rotational position of a stepping motor and generating a detection signal, a measurement section for measuring a time interval of the detection signal, a determination section for determining whether or not a measurement value corresponding to the time interval between the detection signals coincides with a reference value corresponding to a rotation time between the specific rotational positions determined based on an operation instruction to the stepping motor, and an information transmitting section for transmitting operation abnormality information to an outside when the measurement value does not coincide with the reference value.

(2) Further, in the monitoring module according to (1), the detection section is a rotation sensor configured to detect the detection signal every time the stepping motor rotates one rotation.

(3) Further, in the monitoring module according to (1) or (2), the determination section determines whether or not the measurement value coincides with the reference value by determining whether or not a difference between the measurement value and the reference value is within a predetermined range.

(4) Further, in the monitoring module according to any one of (1) to (3), the stepping motor is used for an installation position adjustment mechanism of a goniometer, a sample stage, a variable slit or a detector.

(5) Further, the monitoring module according to any one of (1) to (4), further comprising a monitoring condition setting section for setting the number of detection signals included in the time interval between the detection signals.

(6) Further, the X-ray diffraction apparatus of the present disclosure is an X-ray diffraction apparatus in which the operation of the stepping motor is monitored, comprising a goniometer for controlling positions of an X-ray source, a sample and a detector, an adjustment mechanism for adjusting an arrangement of a sample stage supporting the sample, and the monitoring module according to (1) to (5), the stepping motor drives at least one of the goniometer or the adjustment mechanism.

(7) Further, the monitoring system of the present disclosure is a monitoring system for monitoring the operation of the stepping motor, comprising the X-ray diffraction apparatus according to (6), and a processing apparatus for controlling the monitoring module, wherein the processing apparatus displays an operation guarantee or an operation abnormality based on the presence or absence of the transmitted operation abnormality information.

(8) Further, in the monitoring system according to in (7), the operation guarantee is numerical information indicating reliability of a relationship between a rotational speed of the stepping motor and the reference value.

### BRIEF DESCRIPTION OF THE DRAWINGS

FIG. 1 is a schematic diagram showing a configuration of the monitoring system of the present disclosure.

FIG. 2 is a block diagram showing a functional configuration of the monitoring module of the present disclosure.

FIG. 3 is a schematic diagram showing an example of a configuration of the monitoring module of the present disclosure.

FIG. 4 is a timing chart showing a pulse signal and a detection signal.

### DETAILED DESCRIPTION

Next, embodiments of the present disclosure are described with reference to the drawings. To facilitate understanding of the description, the same reference numerals are assigned to the same components in the respective drawings, and duplicate descriptions are omitted.

### [Principle]

In the conventional operation monitoring based on the position, it is checked whether there is any abnormality in the number of pulse signals between detection signals of the rotation sensor. In this case, even if there is an abnormality in the rotational speed, if there is no abnormality in the position, it is determined that there is no abnormality. However, the measurement using the X-ray diffraction apparatus 100 has a specific situation in which reliability is guaranteed by driving the goniometer 130, the sample stage 140 and the like at a constant speed. Therefore, in this field, it is highly useful if the art of monitoring the time it takes for the rotating shaft of the stepping motor to rotate a certain angle can be applied to the continuous monitoring. The present disclosure is premised on these circumstances and based on an unconventional idea of monitoring time rather than monitoring position.

### [Monitoring System]

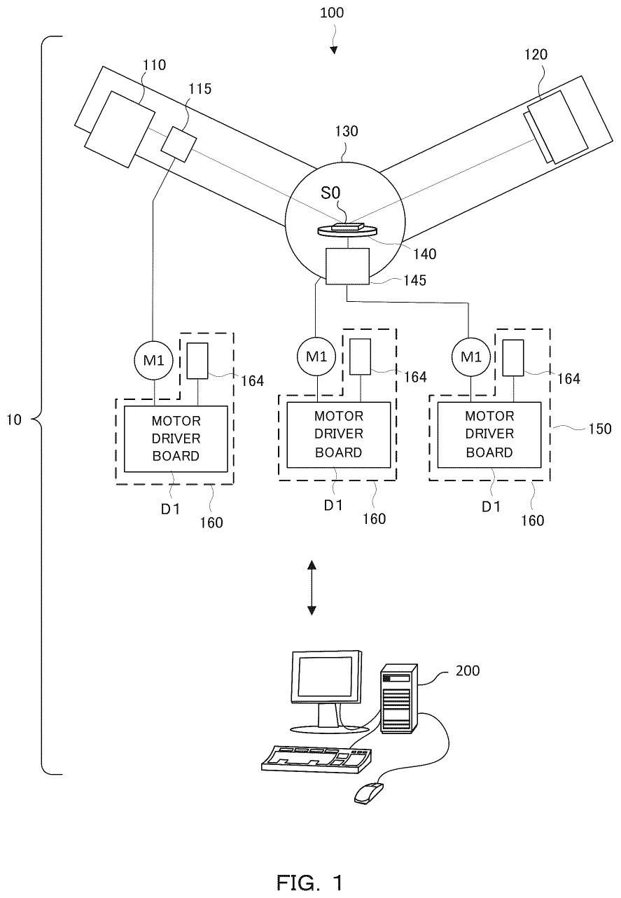

FIG. 1 is a schematic diagram showing a configuration of a monitoring system 10. The monitoring system 10 comprises an X-ray diffraction apparatus 100 and a processing apparatus 200. The X-ray diffraction apparatus 100 irradiates the sample S0 with X-rays, detects scattered X-rays, and enables X-ray diffraction measurement. The X-ray diffraction apparatus 100 drives the inside respective mechanisms with the stepping motor M1 and the monitoring module 160 monitors that the stepping motor M1 rotates the rotation shaft at a constant rotational speed.

### [Processing Apparatus]

The processing apparatus 200 controls the operation of the X-ray diffraction apparatus 100 and displays the information transmitted from the monitoring module 160. For example, the operation guarantee or the operation abnormality is displayed based on the presence or absence of the transmitted operation abnormality information. The processing apparatus 200 is configured by a computer formed by connecting a CPU (Central Processing Unit), a ROM (Read Only Memory), a RAM (Random Access Memory), and a memory to a bus. The processing apparatus 200 may be a PC terminal or a server on a cloud. Not only the whole apparatus but also part of the apparatus or some functions of the apparatus may be provided on the cloud.

### [X-ray Diffraction Apparatus]

The X-ray diffraction apparatus 100 comprises an X-ray source 110, a variable slit 115, a detector 120, a goniometer 130, a sample stage 140, an adjusting device 145, a stepping motor M1 and a monitoring module 160. Although the example shown in FIG. 1 is simplified, in practice, the X-ray diffraction apparatus 100 may comprise a sample rotation and swinging mechanism, a detector installation position adjustment mechanism and other driving mechanisms.

The X-ray source 110 generates X-rays and irradiates the X-rays toward the sample. The variable slit 115 is a slit in which the width of the opening is variable. The detector 120 detects X-rays scattered by the sample S0. The goniometer 130 is controlled in response to the measurement to control the position of the X-ray source 110, the sample S0 and the detector 120. The goniometer 130 may be of any of horizontal rotation type, vertical type or stationary sample type. The scanning axis of the goniometer 130 may include an in-plane (2θχ) axis in addition to the θ axis, the 2θ axis, the tilt axis and the in-plane rotation axis. The sample stage 140 supports the sample S0. The adjustment mechanism 145 adjusts the arrangement of the sample stage 140 that supports the sample S0. The arrangement includes not only a position but also an orientation and a posture.

The stepping motor M1 transmits the rotational force of the rotation shaft to the variable slits 115, the goniometer 130 and the adjustment mechanism 145 and drives them. In addition, if there is a rotation and swinging mechanism of the sample, they may also be driven. Note that, although the same reference numerals are used for convenience, the stepping motors M1 for driving the respective mechanisms are provided independently.

The monitoring module 160 monitors the operation of the stepping motor M1 used in the X-ray diffraction apparatus 100. For example, a stepping motor M1 used for the goniometer 130, the sample stage 140 or the slit-variable mechanism, and the installation position adjusting mechanism of the detector can be monitored. Thus, it is possible to guarantee that the rotational speed of the rotary shaft by the stepping motor M1 is constant with respect to the driving such as scanning of the measurement by the gonioarm, rotation and swinging by the sample stage 140, adjustment of the opening width by the variable slit 115, and adjustment of the camera length by the installation position adjustment mechanism of the detector.

### [Configuration of Monitoring Module]

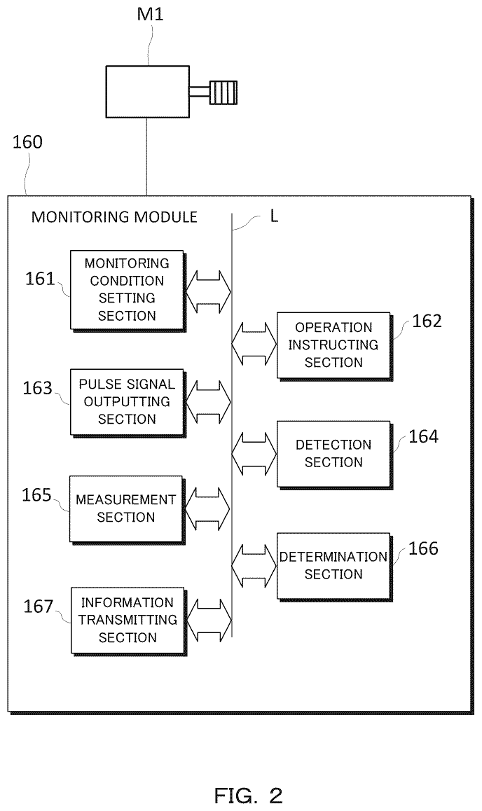

FIG. 2 is a block diagram showing a functional configuration of the monitoring module 160. The monitoring module 160 comprises a monitoring condition setting section 161, an operation instructing section 162, a pulse signal outputting section 163, a detection section 164, a measurement section 165, a determination section 166 and an information transmitting section 167. Among them, the monitoring condition setting section 161, the operation instructing section 162, the pulse signal outputting section 163, the measuring section 165, the determining section 166 and the information transmitting section 167 are configured by integrated circuits of the motor driver board D1 in the pulse motor controller. The integrated circuitry is preferably FPGA (Field Programmable Gate Array). Instead of the board, it may be configured by a control device such as a PLC

### (Programmable Logic Controller).

The monitoring condition setting section 161 sets a monitoring condition such as a time interval between the detection signals before the operation. The time interval of the detection signals is a time interval for each predetermined number of detection signals. It may be for one signal or two signals. As the monitoring condition, for example, the number of rotations of the motor is set, and the time between detection signals for each number of motor rotations can be monitored. Further, it is also possible to set a threshold value for the difference between the time interval of the measured detection signals and the reference value. It is determined whether or not the difference is within a predetermined range based on the set threshold value, and it is possible to determine whether or not there is an operation abnormality. The predetermined range is preferably set according to an instruction from the processing apparatus 200 because the appropriate range is different according to the measurement.

The operation instructing section 162 calculates the number of pulse signals and the pulse signal rate required for moving by the operation of the stepping motor M1 and outputs an operation starting command. The pulse signal outputting section 163 outputs a pulse signal to the driver of the stepping motor M1 in accordance with the operation starting command.

The detection section 164 detects that the rotation shaft of the stepping motor M1 is at a specific rotation position and generates a detection signal. The specific rotation position refers to a position at every constant angle interval and may be, for example, 60°, 120°, 180°,., every 60°, or 360°, 720°,., every 360°.

The detection section 164 is a rotation sensor that outputs a detection signal every time the rotation shaft of the stepping motor M1 rotates by a constant angle. In particular, a rotation sensor capable of detecting one rotation (so-called INDEX sensor) is preferably used. As a result, a low-cost monitoring system can be configured as compared with a case where an encoder is used. In addition, since the size of the motor unit is reduced, the size of the attachment can be reduced. When the rotation sensor is used, it is assumed that a motor driver board having a function of detecting an abnormal operation of the motor is used.

The rotation sensor may comprise, for example, a disk with a notch attached to the rotation shaft of the stepping motor M1 and a photosensor that transmits a signal at the notch position. By aligning the center axis of the disk and the center axis of the rotation shaft and forming one notch in the disk, one detection signal per rotation is obtained from the rotation sensor. In addition, the rotation may be detected by using a disk with a marker, a magnetic sensor or the like.

The rotation sensor does not necessarily have to be a rotation sensor capable of detecting a signal once per rotation, as long as the rotation sensor outputs a detection signal every time the rotation shaft rotates at every constant angle interval. The rotation sensor may detect one signal at every ½ rotation, or one signal at every ⅓ rotation.

It is also possible to use an encoder as a type of rotation sensor. The encoder is provided with detection target parts at a plurality of positions on the disk, and outputs a detection signal when the detection target part is detected by the sensor. Conventional rotation sensors are used to confirm the position. By measuring the time interval between the detected signals, the rotational speed of the stepping motor M1 can be guaranteed.

The measurement section 165 measures the time interval between the detection signals obtained from the detection section 164. The determination section 166 determines whether or not the measured value corresponding to the time interval between the detection signals is a reference value corresponding to the rotation time between the specified rotation positions determined based on the operation instruction to the stepping motor M1. The “measured value” includes not only the observed value but also an equivalent value calculated from the observed value. It is preferable to determine whether or not the measured value coincides with the reference value based on whether or not the difference between the measured value and the reference value is within a predetermined range. Thus, it can be determined that there is an abnormality when the time for which the rotation shaft of the stepping motor M1 moves between the specified rotation positions is not constant. Note that the reference value and the measured value may be the time itself that the rotation shaft rotates between specific rotation positions or may be a numerical value such as a rotational speed or a time per rotation equivalent thereto.

When the measured value is not the reference value, the information transmitting section 167 transmits the operation abnormality information to the outside. Thus, it can be guaranteed that the components of the X-ray diffraction apparatus 100 are driven at a constant speed, and the traceability of each measurement profile can be maintained. Note that the operation abnormality information may be transmitted by not transmitting and receiving normal information.

### Configuration Example

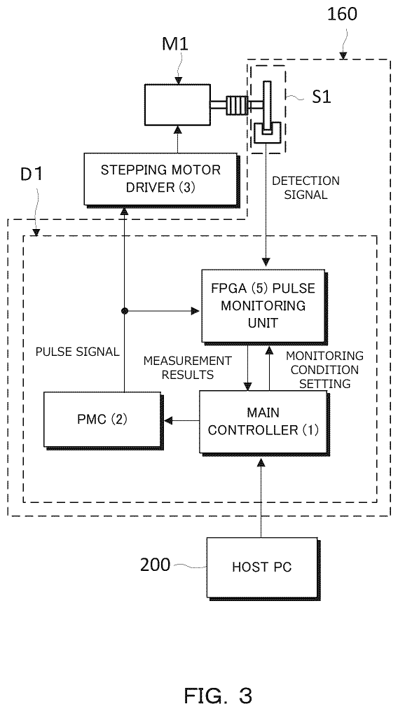

FIG. 3 is a schematic diagram showing an example of a configuration of the monitoring module 160. In the configuration shown in FIG. 3, first, based on a command from HOST PC (processing apparatus), the main controller (1) calculates the number of pulse signals and the pulse signal rate required for driving the respective mechanisms and moving by the measurement operation, and before the operation, sets the monitoring condition such as the response time of the rotation sensor S1 during the constant speed operation (excluding the acceleration/deceleration time) in the operation to FPGA (5). By this setting, it is also possible to measure, for example, the time between the detection signals for every 100 rotations of the motor. It can also be guaranteed, for example, that the operation has been performed at a rate of 20 deg/min±0.05% of less in the measurement of 20 deg/min.

The main controller (1) sets the number of pulse signals, the pulse signal rate and the operation starting command to PMC (2). Then, PMC (2) outputs a pulse signal to the stepping motor driver (3). Note that PMC is an abbreviation for Pulse Motor Controller. Further, the main controller and FPGA may be considered as an integral part of the configuration.

FPGA (5) of the motor driver board D1 counts the input pulse signal and measures the time interval between the detection signals. Every time the stepping motor M1 makes one rotation (depending on the resolution, for example, 500 pulse), a detection signal is output from the rotation sensor once. The measurement result of the time interval of the detection signal is transmitted to the main controller (1).

With this configuration, when there is an abnormality in a peripheral circuit of the PMC and the pulse signal is not output, the abnormality can be detected that the pulse signal is not output even though the operation has been started. If the pulse signal is output, but the detection signal is not detected even when it takes the time of 1 or more rotations of the motor, it is possible to recognize that a motor step-out or a failure of the rotation sensor (without output) has occurred, and thus it is possible to detect an abnormality.

Each time the stepping motor M1 rotates one time, a detection signal from the rotation sensor is output once. During the constant speed operation of the stepping motor M1 (excluding the acceleration/deceleration time), the time interval between the times at which the rotational sensor reacts is constant.

Conventionally, the reliability of the measurement cannot be guaranteed because it is not known whether the driving mechanism is actually in motion as the setting in the measurement at a rate such as, for example, a 20 deg/min (or 20 mm/min). The operation rate of the motor can be measured during the measurement by measuring the time interval between the detection signals with FPGA (5). Thus, the operation of the stepping motor M1 can be guaranteed in the measurement. It is also possible to guarantee the operation of the driving mechanism for each angle or position within the measurement range.

For example, when the measurement is performed for the range of the diffractive angle from 10 to 15 deg at 20 deg/min, a following numerical range indicating the reliability can also be recognized.

| | |
|---|---|
| 10~11 deg | 20 deg/min ± 0.03% |
| 11~12 deg | 20 deg/min ± 0.02% |
| 12~13 deg | 20 deg/min ± 0.01% |
| 13~14 deg | 20 deg/min ± 0.03% |
| 14~15 deg | 20 deg/min ± 0.02% |

The stepping motor M1 is used not only for driving the goniometer in the measurement, but also for various driving mechanisms such as a slit adjusting mechanism of an incident and receiving optical system and a rotation and swinging mechanism of a sample stage. In the measurement of X-ray diffraction, there is a measurement of changing the diffraction angle while automatically changing the slit width of the incident side so that the irradiation width on the sample surface becomes constant, and a measurement of rotating or swinging the sample at a constant speed in order to reduce the effect of orientation and coarse particles. With the above configuration, the operation of the stepping motor can be guaranteed with respect to the driving mechanism of each axis during measurement. In addition, since the motor speed at the time of movement is recognized by the main controller (1), it is possible to guarantee not only the operation at the time of measurement but also the operation at the time of simple movement by a driving mechanism. For example, since the motor is monitored to move at the speed at the time of axial movement when the axial movement is performed prior to the start of the measurement, it can be guaranteed that the slit width of the variable slit, XY coordinate position of the sample stage or the camera length of the detector has correctly reached the position as set.

### [Operation of Monitoring Module]

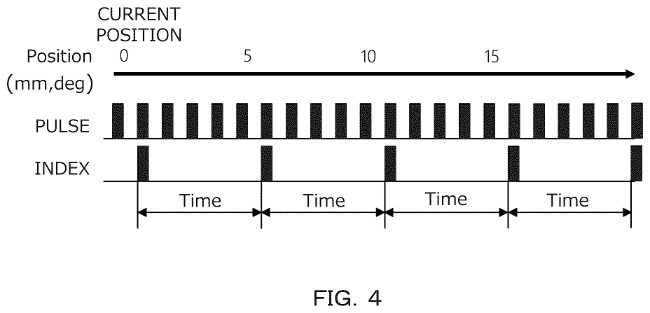

An operation example of the monitoring module 160 configured as described above is described below. FIG. 4 is a timing chart showing a pulse signal and a detection signal. The pulse signal is a signal for operating the stepping motor M1, and the detection signal is represented as “INDEX” and indicates a signal detected by the detection section 164.

When an instruction is given to the stepping motor M1 from the control apparatus at the time of measurement using the X-ray diffraction apparatus 100, a monitoring condition is set in accordance with the instruction, and an operation instruction is given. Then, the pulse signal outputting section 163 outputs a pulse signal at regular intervals so as to be driven at a rotational speed in accordance with the operation instruction. The stepping motor M1 rotates the rotation shaft by this pulse signal.

On the other hand, the detection section 164 outputs a detection signal every time the stepping motor M1 rotates by a constant angle. The measurement section 165 measures a time interval taken for a predetermined number of detection signals as a measured value of a time taken to rotate by a constant angle.

The determination section 166 determines whether or not the measured value coincides with the reference value when the rotation time between the specific rotation positions determined based on the operation instruction is set as the reference value. For example, if the number of pulse signals per detection signal is verified, it is possible to confirm the presence or absence of step-out of the stepping motor M1, but it is not possible to confirm that the rotational speed is constant. However, it is possible to guarantee the rotational speed by comparing the time taken between the specific rotation positions calculated along the operation instruction with the time interval between the detection signals measured by the sensor. When the calculated rotational speed does not coincide with the reference value, the information transmitting section 167 transmits the operation abnormality information to the processing apparatus 200. The processing apparatus 200 can immediately detect the device failure by notifying the occurrence of operation abnormality of the motor on the application. In this way, the operation of the stepping motor M1 can be monitored.

### [Display of Reliability]

The operation guarantee displayed by the processing apparatus 200 is preferably numerical information indicating the reliability of the relationship between the rotational speed of the stepping motor and the reference value. The numerical value indicating the reliability is, for example, a numerical value range±x % including the detected stepping motor rotational speed with respect to the reference value. Thus, the user can confirm the objective reliability of the measurement instantly when using the X-ray diffraction apparatus.

### DESCRIPTION OF SYMBOLS

10 monitoring system
100 X-ray diffraction apparatus
110 X-ray source
115 variable slit
120 detector
130 goniometer
140 sample stage
145 adjustment mechanism
160 monitoring module
161 monitoring condition setting section
162 operation instructing section
163 pulse signal outputting section
164 detection section
165 measurement section
166 determination section
167 information transmitting section
200 processing apparatus
D1 motor driver board
M1 stepping motor
S0 sample
S1 rotation sensor

What is claimed is:

1. A monitoring module for monitoring an operation of a stepping motor used in an X-ray diffraction apparatus, comprising:
a rotation sensor configured to detect a specific rotational position of a stepping motor and generate a detection signal; and
circuitry configured to
measure a time interval of the detection signal, determine whether or not a measurement value corresponding to the time interval between the detection signals coincides with a reference value corresponding to a rotation time between the specific rotational positions determined based on an operation instruction to the stepping motor, and
transmit operation abnormality information to another device when the measurement value does not coincide with the reference value.

2. The monitoring module according to claim 1, wherein the rotation sensor is configured to detect the detection signal every time the stepping motor rotates one rotation.

3. The monitoring module according to claim 1, wherein the circuitry is further configured to
determine whether or not the measurement value coincides with the reference value by determining whether or not a difference between the measurement value and the reference value is within a predetermined range.

4. The monitoring module according to claim 1, wherein the stepping motor is used for an installation position adjustment mechanism of a goniometer, a sample stage, a variable slit or a detector.

5. The monitoring module according to claim 1, wherein the circuitry is further configured to
set the number of detection signals included in the time interval between the detection signals.

6. An X-ray diffraction apparatus in which operation of the stepping motor is monitored, comprising:
a goniometer for controlling positions of an X-ray source, a sample and a detector;
an adjustment mechanism for adjusting an arrangement of a sample stage supporting the sample; and
the monitoring module according to claim 1, wherein the stepping motor drives at least one of the goniometer or the adjustment mechanism.

7. A monitoring system for monitoring the operation of the stepping motor, comprising:
the X-ray diffraction apparatus according to claim 6, and
a processing apparatus for controlling the monitoring module, wherein the processing apparatus displays an operation guarantee or an operation abnormality based on the presence or absence of the transmitted operation abnormality information.

8. The monitoring system according to claim 7, wherein the operation guarantee is numerical information indicating reliability of a relationship between a rotational speed of the stepping motor and the reference value.
